(19) United States
(12) Patent Application Publication
(10) Pub. No.: US 2025/0126878 A1
(43) Pub. Date: Apr. 17, 2025

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Yuusuke OOSHIMA, Matsumoto-city (JP); Takashi YOSHIMURA, Matsumoto-city (JP); Hiroshi TAKISHITA, Matsumoto-city (JP); Shuntaro YAGUCHI, Matsumoto-city (JP); Hidenori TSUJI, Higashimurayama-city (JP)

(21) Appl. No.: 19/000,251

(22) Filed: Dec. 23, 2024

Related U.S. Application Data
(63) Continuation of application No. PCT/JP2023/043492, filed on Dec. 5, 2023.

(30) Foreign Application Priority Data
Dec. 13, 2022 (JP) 2022-198955

(51) Int. Cl. H10D 84/00; H10D 62/53; H10D 84/01

(52) U.S. Cl. CPC H10D 84/161; H10D 62/53; H10D 84/01

(57) ABSTRACT

Provided is a semiconductor device, comprising a semiconductor substrate with an upper surface and a lower surface, wherein: the semiconductor substrate has one or more hydrogen peaks, which are peaks of hydrogen chemical concentration, in a depth direction, and the one or more hydrogen peaks include a deepest peak furthest away from the lower surface of the semiconductor substrate; the semiconductor substrate has a lower region from the lower surface to the deepest peak, and an upper region arranged from the deepest peak to the upper surface; and for at least one of a carbon chemical concentration or an oxygen chemical concentration, a concentration in the lower region is twice or more of a concentration of the upper region.

The contents of the following patent applications are incorporated herein by reference: NO. 2022-198955 filed in JP on Dec. 13, 2022 NO. PCT/JP2023/043492 filed in WO on Dec. 5, 2023

BACKGROUND

### 1. Technical Field

The present invention relates to a semiconductor device and a manufacturing method of

the semiconductor device.

### 2. Related Art

A semiconductor device is known to have hydrogen ions such as protons implanted into a semiconductor substrate (for example, see Patent Document 1 and 2).

Patent Document 1: Specification of U.S. Patent Application Publication No. 2016/0141399.

Patent Document 2: Specification of U.S. Patent Application Publication No. 2015/0076650.

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates an example of a cross section e-e in FIG. 2.

FIG. 4 illustrates one example of each distribution of a doping concentration, a hydrogen chemical concentration, an oxygen chemical concentration and a carbon chemical concentration in a line f-f of FIG. 3.

FIG. 5 illustrates another example of each distribution of the doping concentration, the hydrogen chemical concentration, the oxygen chemical concentration and the carbon chemical concentration in the line f-f of FIG. 3.

FIG. 6 illustrates another example of each distribution of the doping concentration, the hydrogen chemical concentration, the oxygen chemical concentration and the carbon chemical concentration in the line f-f of FIG. 3.

FIG. 7 illustrates another example of each distribution of the doping concentration, the hydrogen chemical concentration, the oxygen chemical concentration and the carbon chemical concentration in the line f-f of FIG. 3.

FIG. 8 illustrates another example of each distribution of the doping concentration, the hydrogen chemical concentration, the oxygen chemical concentration and the carbon chemical concentration in the line f-f of FIG. 3.

FIG. 9 illustrates one example of relative positions of an oxygen peak 232 and a carbon peak 242.

FIG. 10 illustrates another example of relative positions of the oxygen peak 232 and the carbon peak 242.

FIG. 11 illustrates another example of each distribution of the doping concentration, the hydrogen chemical concentration, the oxygen chemical concentration and the carbon chemical concentration in the line f-f of FIG. 3.

FIG. 12 illustrates another example of each distribution of the oxygen chemical concentration and the carbon chemical concentration in the line f-f of FIG. 3.

FIG. 13 illustrates a view showing part of a process of a manufacturing method of the semiconductor device 100.

FIG. 14 illustrates an outline of the manufacturing method of the semiconductor device 100.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of the X axis, the Y axis, and the Z axis. The orthogonal coordinate axes merely specify relative positions of components, and do not limit a specific direction. For example, the Z axis is not limited to indicate the height direction with respect to the ground. It is to be noted that the + Z-axis direction and the − Z-axis direction are directions opposite to each other. When the Z-axis direction is described without describing the signs, it means that the direction is parallel to the +Z axis and the −Z axis.

In the present specification, orthogonal axes parallel to the upper surface and the lower surface of the semiconductor substrate are referred to as the X-axis and the Y-axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including the X-axis direction and the Y-axis direction.

A region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of an N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by the combination of at least a vacancy (V) and hydrogen (H). Alternatively, interstitial Si—H in which interstitial silicon (Si-i) in a silicon semiconductor is attached to hydrogen, and CiOi-H in which interstitial carbon (Ci) is attached to interstitial oxygen (Oi) and hydrogen also function as a donor which supplies electrons. In the present specification, the VOH defect, the CiOi-H, or the interstitial Si—H may be referred to as the hydrogen donor.

In the semiconductor substrate in the present specification, bulk donors of the N type are distributed throughout. The bulk donor is a dopant donor substantially uniformly contained in an ingot during the manufacture of the ingot from which the semiconductor substrate is made. The bulk donor in this example is an element other than hydrogen. The bulk donor dopant is, for example, phosphorous, antimony, arsenic, selenium, or sulfur, but the invention is not limited to these. The bulk donor in this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (D0) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of a P type or an N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is the SI base unit system unless otherwise noted. Although a unit of length may be indicated by cm, it may be converted to meters (m) before calculations.

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

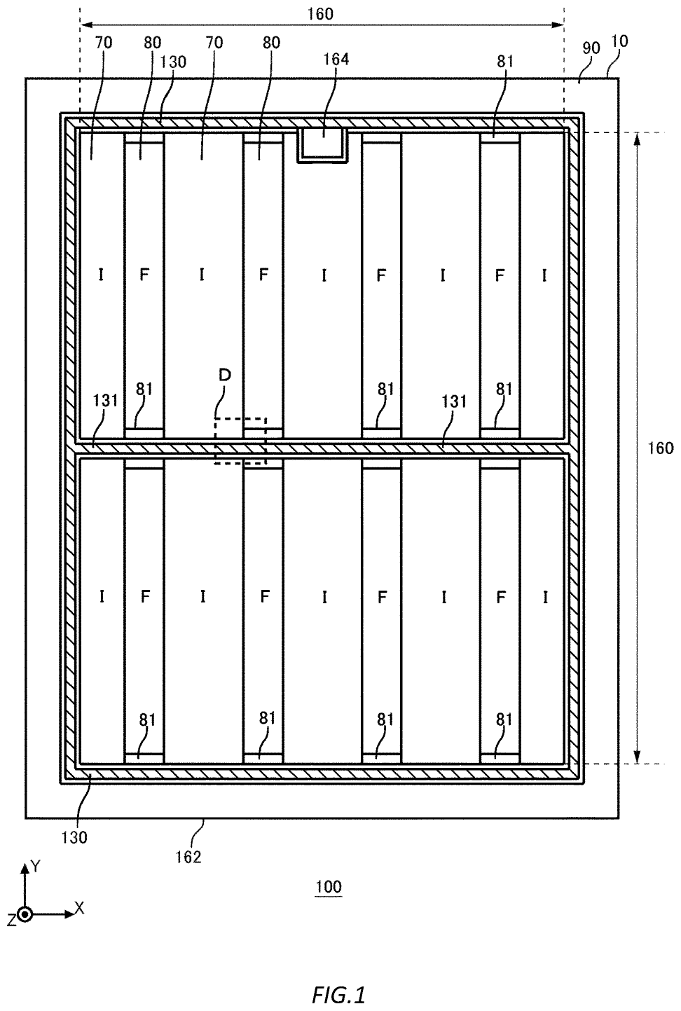

FIG. 1 illustrates a top view showing an example of a semiconductor device 100 according to one embodiment of the present invention. FIG. 1 shows a position at which each member is projected on an upper surface of a semiconductor substrate 10. FIG. 1 shows merely some members of the semiconductor device 100, and omits illustrations of some members. The semiconductor device 100 includes the semiconductor substrate 10. The

semiconductor substrate 10 is a substrate that is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side.

The semiconductor substrate 10 in this example has two sets of end sides 162 opposite to each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but is omitted in FIG. 1. The active portion 160 may refer to a region that overlaps with the emitter electrode in a top view. In addition, a region sandwiched between active portions 160 in a top view may also be included in the active portion 160.

The active portion 160 is provided with at least one of a transistor portion 70 including a transistor element such as an insulated gate bipolar transistor (IGBT) and a diode portion 80 including a diode element such as a freewheeling diode (FWD). In the example shown in FIG. 1, the transistor portions 70 and the diode portions 80 are alternately arranged along a predetermined array direction (the X-axis direction in this example) at the upper surface of the semiconductor substrate 10. The semiconductor device 100 in this example is a reverse-conducting IGBT (RC-IGBT).

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in a top view may be referred to as an extending direction (the Y-axis direction in FIG. 1). Each of the transistor portions 70 and the diode portions 80 may have a longitudinal length in the extending direction.

In other words, the length of each of the transistor portions 70 in the Y-axis direction is larger than the width in the X-axis direction. Similarly, the length of each of the diode portions 80 in the Y-axis direction is larger than the width in the X-axis direction. The extending direction of the transistor portion 70 and the diode portion 80, and the longitudinal direction of each trench portion described below may be the same.

Each of the diode portions 80 includes a cathode region of an N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of a P+ type may be provided in a region other than the cathode region. In the present specification, the diode portion 80 may also include an extension region 81 where the diode portion 80 extends to a gate runner described below in the Y-axis direction. The collector region is provided on a lower surface of the extension region 81.

The transistor portion 70 has the collector region of the P+ type in a region in contact with the lower surface of the semiconductor substrate 10. In addition, in the transistor portion 70, an emitter region of an N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 in this example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in a top view. When the semiconductor device 100 is mounted, each pad may be connected to an external circuit through a wiring such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner of the present example has an outer circumferential gate runner 130 and an active-side gate runner 131. The outer circumferential gate runner 130 is arranged between the active portion 160 and the end side 162 of the semiconductor substrate 10 in a top view. The outer circumferential gate runner 130 in this example encloses the active portion 160 in a top view. A region enclosed by the outer circumferential gate runner 130 in a top view may be defined as the active portion 160. In addition, a well region is formed below the gate runner. The well region is a P+ type region having a higher concentration than the base region described below, and is formed up to a position deeper than a position of the base region from the upper surface of the semiconductor substrate 10. A region enclosed by the well region in a top view may be the active portion 160.

An outer circumferential gate runner 130 is connected to the gate pad 164. The outer circumferential gate runner 130 is arranged above the semiconductor substrate 10. The outer circumferential gate runner 130 may be a metal wiring including aluminum or the like.

The active-side gate runner 131 is provided in the active portion 160. Providing the active-side gate runner 131 in the active portion 160 can reduce a variation in a wiring line length from the gate pad 164 for each region of the semiconductor substrate 10.

The outer circumferential gate runners 130 and the active-side gate runner 131 are connected to the gate trench portion of the active portion 160. The outer circumferential gate runners 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 in this example is provided extending in the X-axis direction so as to cross the active portion 160 substantially at the center of the Y-axis direction from one outer circumferential gate runner 130 to another outer circumferential gate runner 130 which sandwich the active portion 160. When the active portion 160 is divided by the active-side gate runner 131, the transistor portions 70 and the diode portions 80 may be alternately arranged in the X-axis direction in each divided region.

The semiconductor device 100 may include a temperature sensing portion (not shown) which is a PN junction diode formed of polysilicon or the like, and a current detection portion (not shown) which simulates an operation of a transistor portion provided in the active portion 160.

The semiconductor device 100 in this example includes an edge termination structure portion 90 between the active portion 160 and the end side 162 in a top view. The edge termination structure portion 90 in this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided enclosing the active portion 160.

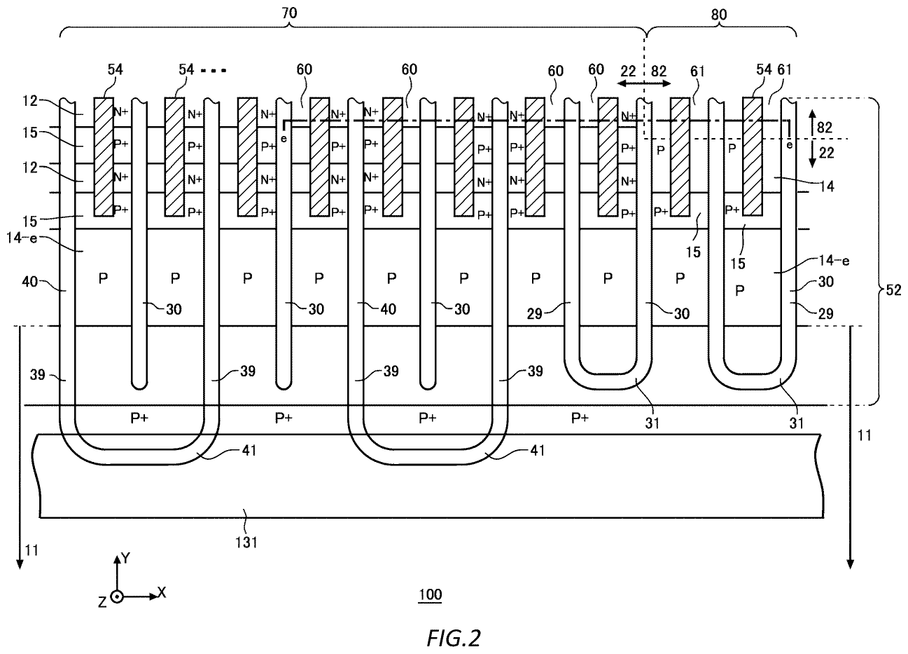

FIG. 2 illustrates an enlarged view of a region D in FIG. 1. The region D is a region including a transistor portion 70, a diode portion 80, and an active-side gate runner 131. A semiconductor device 100 in this example includes gate trench portions 40, dummy trench portions 30, a well region 11, emitter regions 12, base regions 14, and contact regions 15 which are provided inside on an upper surface side of a semiconductor substrate 10. The gate trench portion 40 and the dummy trench portion 30 each are an example of the trench portion. In addition, the semiconductor device 100 in this example includes an emitter electrode 52 and the active-side gate runner 131 that are provided on or above the upper surface of the semiconductor substrate 10. The emitter electrode 52 and the active-side gate runner 131 are provided in isolation from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film in this example, a contact hole 54 is provided penetrating the interlayer dielectric film. In FIG. 2, each contact hole 54 is hatched with the diagonal lines.

The emitter electrode 52 is provided above the gate trench portions 40, the dummy

trench portions 30, the well region 11, the emitter regions 12, the base regions 14, and the contact regions 15. The emitter electrode 52 is in contact with the emitter regions 12, the contact regions 15, and the base regions 14 at the upper surface of the semiconductor substrate 10, through the contact holes 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y-axis direction. The dummy conductive portions of the dummy trench portions 30 may not be connected to the emitter electrode 52 and a gate conductive portion, and may be controlled to be at a potential different from a potential of the emitter electrode 52 and a potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y-axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least a part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in a contact hole.

The well region 11 is provided overlapping the active-side gate runner 131. The well region 11 is provided so as to extend with a predetermined width even in a range not overlapping the active-side gate runner 131. The well region 11 in this example is provided away from an end of the contact hole 54 in the Y-axis direction toward the active-side gate runner 131 side. The well region 11 is a region of a second conductivity type having a higher doping concentration than the base region 14. The base region 14 of this example is a P type, and the well region 11 is a P+ type.

Each of the transistor portion 70 and the diode portion 80 has a plurality of trench portions arrayed in an array direction. In the transistor portion 70 in this example, one or more gate trench portions 40 and one or more dummy trench portions 30 are alternately provided along the array direction. In the diode portion 80 in this example, the plurality of dummy trench portions 30 are provided along the array direction. In the diode portion 80 in this example, the gate trench portion 40 is not provided.

The gate trench portion 40 in the present example may include two linear portions 39 extending along an extending direction perpendicular to the array direction (trench portions which are linear along the extending direction), and the edge portion 41 connecting the two linear portions 39. The extending direction in FIG. 2 is the Y-axis direction.

At least a part of the edge portion 41 is preferably provided in a curved shape in a top view. By connecting between end portions of the two linear portions 39 in the Y-axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similarly to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y-axis direction of the gate trench portion 40 and the dummy trench portion 30 are provided in the well region 11 in a top view. In other words, the bottom portion in a depth direction of each trench portion is covered with the well region 11 at the end portion in the Y-axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion in this example is provided extending in the extending direction (the Y-axis direction) along the trench, at the upper surface of the semiconductor substrate 10. In this example, mesa portions 60 are provided in the transistor portion 70, and mesa portions 61 are provided in the diode portion 80. In a case of simply mentioning “mesa portion” in the present specification, the portion refers to each of a mesa portion 60 and a mesa portion 61.

Each of the mesa portions is provided with base regions 14. In the mesa portion, a region arranged closest to the active-side gate runner 131 among the base regions 14 exposed on the upper surface of the semiconductor substrate 10 is defined as a base region 14-e. While FIG. 2 shows a base region 14-e arranged at one end portion of each of the mesa portions in the extending direction, a base region 14-e is arranged also at another end portion of each of the mesa portions. Each of the mesa portions may be provided with at least one of an emitter region 12 of a first conductivity type or a contact region 15 of the second conductivity type in a region sandwiched between base regions 14-e in a top view. The emitter region 12 in this example is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 includes the emitter region 12 exposed on the upper surface of the semiconductor substrate 10. The emitter region 12 is provided in contact with the gate trench portion 40. The mesa portion 60 in contact with the gate trench portion 40 may be provided with the contact regions 15 exposed on the upper surface of the semiconductor substrate 10.

Each of the contact region 15 and the emitter region 12 in the mesa portion 60 is provided from one trench portion to another trench portion in the X-axis direction. As an example, the contact regions 15 and the emitter regions 12 in the mesa portion 60 are alternately arranged along the extending direction of the trench portion (the Y-axis direction).

In another example, the contact regions 15 and the emitter regions 12 of the mesa portion 60 may be provided in a striped pattern along the extending direction of the trench portion (the Y-axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 at the upper surface of the mesa portion 61. The base region 14 may be arranged throughout the region sandwiched between the contact regions 15.

The contact hole 54 is provided above each mesa portion. The contact hole 54 is arranged in the region sandwiched between the base regions 14-e. The contact hole 54 in this example is provided above each of the contact regions 15, the base region 14, and the emitter regions 12. The contact hole 54 is not provided in regions corresponding to the base region 14-e and the well region 11. The contact hole 54 may be arranged at a center of the mesa portion 60 in the array direction (the X-axis direction).

In the diode portion 80, a cathode region 82 of the N+ type is provided in a region in direct contact with the lower surface of the semiconductor substrate 10. On the lower surface of the semiconductor substrate 10, a collector region of the P+ type 22 may be provided in a region where the cathode region 82 is not provided. The cathode region 82 and a collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged away from the well region 11 in the Y-axis direction. With this configuration, the distance between a region of a P+ type (the well region 11) having a comparatively high doping concentration and formed up to the deep position, and the cathode region 82 is ensured, so that the breakdown voltage can be improved. The end portion in the Y-axis direction of the cathode region 82 in this example is arranged farther away from the well region 11 than the end portion in the Y-axis direction of the contact hole 54. In another example, the end portion in the Y-axis direction of the cathode region 82 may be arranged between the well region 11 and the contact hole 54.

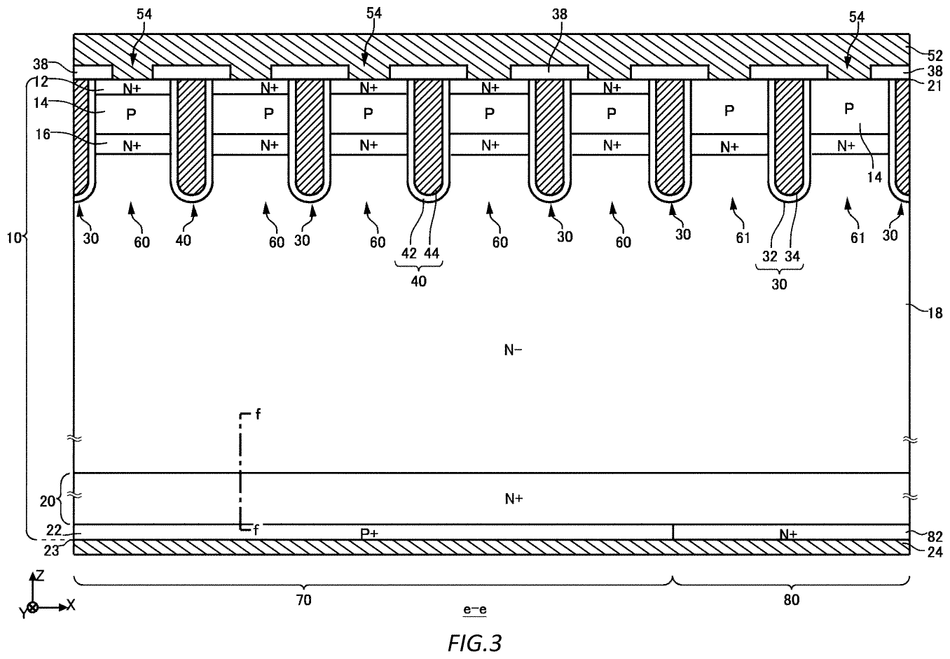

FIG. 3 illustrates an example of a cross section e-e in FIG. 2. The cross section e-e is the XZ plane passing through an emitter region 12 and a cathode region 82. A semiconductor device 100 in this example includes a semiconductor substrate 10, an interlayer dielectric film 38, an emitter electrode 52, and a collector electrode 24 in the cross section.

The interlayer dielectric film 38 is provided on an upper surface of the semiconductor substrate 10. The interlayer dielectric film 38 is a film including at least one layer of a dielectric film such as silicate glass to which an impurity such as boron or phosphorous is added, a thermal oxide film, and other dielectric films. The interlayer dielectric film 38 is provided with a contact hole 54 described with reference to FIG. 2.

The emitter electrode 52 is provided above the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z-axis direction) is referred to as a depth direction.

The semiconductor substrate 10 includes a drift region 18 of an N type or an N− type. The drift region 18 is provided in each of a transistor portion 70 and a diode portion 80.

In the mesa portion 60 of the transistor portion 70, an N+ type of emitter region 12 and a P type of base region 14 are provided in order from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed on the upper surface 21 of the semiconductor substrate 10 and is provided in contact with a gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 in this example is provided in contact with the emitter region 12. The base region 14 may be in contact with the trench portions on both sides of the mesa portion 60.

The accumulation region 16 is provided below the base region 14. The accumulation region 16 is a region of the N+ type having a higher doping concentration than the drift region 18. That is, the accumulation region 16 has a higher donor concentration than the drift region 18. Providing the accumulation region 16 having a high concentration between the drift region 18 and the base region 14 can increase a carrier implantation enhancement effect (IE effect) and reduce an on-voltage. The accumulation region 16 may be provided so as to cover the entire lower surface of the base region 14 in each mesa portion 60.

The mesa portion 61 of the diode portion 80 is provided with the P type of base region 14 in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, an N+ type buffer region 20 may be provided below the drift region 18. The doping concentration of the buffer region 20 is higher than the doping concentration of the drift region 18. The buffer region 20 may have a concentration peak having a higher doping concentration than the doping concentration of the drift region 18. The doping concentration of the concentration peak refers to a doping concentration at the local maximum of the concentration peak. In addition, as the doping concentration of the drift region 18, an average value of doping concentrations in the region where the doping concentration distribution is substantially flat may be used.

The buffer region 20 in this example may have two or more concentration peaks in the depth direction (the Z-axis direction) of the semiconductor substrate 10. The concentration peak of the buffer region 20 may be provided at the same depth position as, for example, a chemical concentration peak of hydrogen (a proton) or phosphorous. The buffer region 20 may function as a field stopper layer which prevents a depletion layer expanding from the lower end of the base region 14 from reaching the collector region 22 of a P+ type and the cathode region 82 of the N+ type.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each of the trench portions is provided from the upper surface 21 of the semiconductor substrate 10 through the base region 14 to below the base region 14. In a region where at least any one of the emitter region 12, the contact region 15, and the accumulation region 16 is provided, each trench portion also passes through the doping regions of these. The configuration of the trench portion penetrating the doping region is not limited to the one manufactured in the order of forming the doping region and then forming the trench portion. The configuration of the trench portions penetrating the doping region also includes a configuration of forming the trench portions and then forming the doping region between the trench portions.

As described above, the transistor portion 70 is provided with the gate trench portion 40 and a dummy trench portion 30. In the diode portion 80, the dummy trench portion 30 is provided, and the gate trench portion 40 is not provided. The boundary in the X-axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided covering the inner wall of the gate trench. The gate dielectric film 42 may be formed by oxidizing or nitriding a semiconductor on the inner wall of the gate trench. The gate conductive portion 44 is provided farther inward than the gate dielectric film 42 in the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided farther inward than the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 in this example are covered with the interlayer dielectric film 38 on the upper surface 21 of the semiconductor substrate 10. Note that the bottom portions of the dummy trench portion 30 and the gate trench portion 40 may be formed in a curved-surface shape (a curved shape in the cross section) convexly downward.

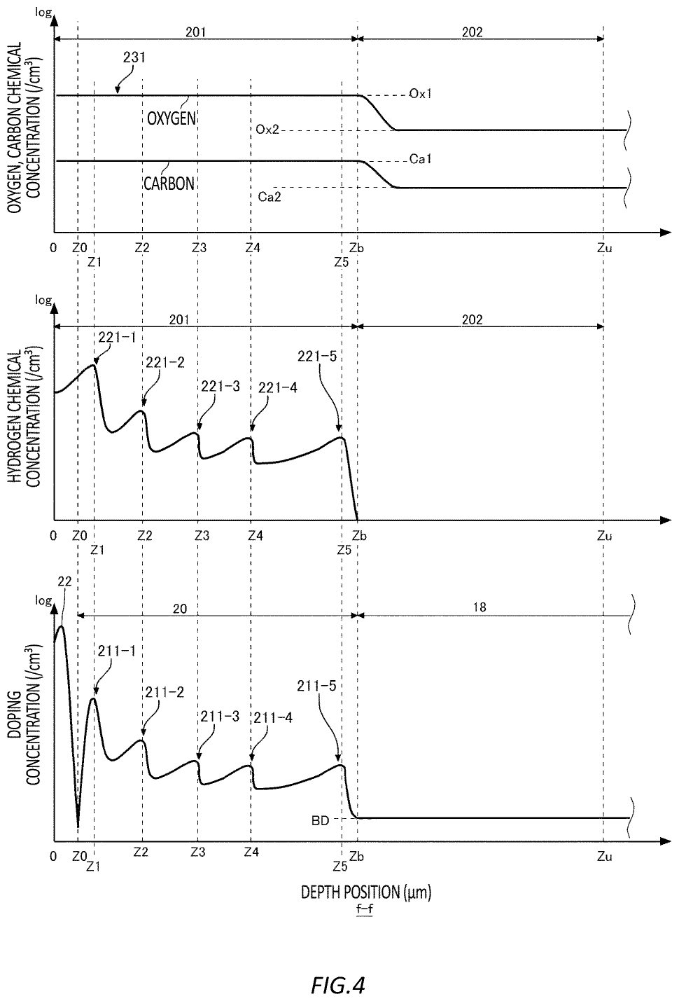

FIG. 4 illustrates one example of each distribution of the doping concentration, the hydrogen chemical concentration, the oxygen chemical concentration and the carbon chemical concentration on the line f-f of FIG. 3. The doping concentration may use the carrier concentration measured by the SRP method or the like. The chemical concentration of hydrogen, oxygen and carbon may be measured by a SIMS method or the like. The line f-f is a line that is parallel to the Z axis, and passes through a part of the buffer region 20 and the drift region 18. A horizontal axis in FIG. 4 represents a depth position (a position in the Z-axis direction) in the semiconductor substrate 10. In the present specification, unless particularly otherwise explained, the lower surface 23 of the semiconductor substrate 10 is the reference position (0) in the Z-axis direction, and the distance from the lower surface 23 is the position in the Z-axis direction.

The drift region 18 is provided above the buffer region 20. The doping concentration of the drift region 18 may be substantially constant. The doping concentration of the drift region 18 may be identical to the bulk donor concentration BD, or may be higher than the bulk donor concentration BD. The doping concentration of the drift region 18 in the present example is identical to the bulk donor concentration BD.

The bulk donor concentration BD may use a minimum value of the chemical concentration of the bulk donors in the semiconductor substrate 10, or may use the chemical concentration of the bulk donors in the center position in the depth direction of the semiconductor substrate 10, or may use an average value of the chemical concentration of the bulk donors in the drift region 18. The bulk donors are dopants other than oxygen or carbon, and are dopants distributed throughout the semiconductor substrate 10. The bulk donors are, for example, phosphorous, but may be arsenic or antimony, not limited thereto. When both of the bulk acceptors of the P type and the bulk donors of the N type are distributed throughout the semiconductor substrate 10, the bulk donor concentration BD is a net concentration determined by the difference between the concentration of the bulk donors and the concentration of the bulk acceptors. The concentration of the bulk donors and the bulk acceptors may use values measured by the SIMS method or the like.

The depth position of the boundary between the drift region 18 and the buffer region 20 is regarded as Zb. The depth position Zb in the present example is a depth position where the doping concentration initially becomes the bulk donor concentration BD in the direction from the buffer region 20 toward the drift region 18.

The buffer region 20 is provided between the drift region 18 and the lower surface 23.

The collector region 22 is provided between the buffer region 20 and the lower surface 23. A boundary position Z0 between the collector region 22 and the buffer region 20 is a position of the PN junction between the collector region 22 and the buffer region 20.

The buffer region 20 in the present example is a region including the hydrogen donors. In the present specification, a region where hydrogen atoms exist (for example, the hydrogen chemical concentration is higher than a detection lower limit) and the doping concentration is higher than the bulk donor concentration BD, which is a region of the N type between the drift region 18 and the collector region 22, is regarded as the buffer region 20.

The buffer region 20 has one or more doping concentration peaks 211 in the depth

direction. In the example shown in FIG. 4, in order from the peak closest to the lower surface 23 of the semiconductor substrate 10, a doping concentration peak 211-1, a doping concentration peak 211-2, a doping concentration peak 211-3, a doping concentration peak 211-4 and a doping concentration peak 211-5 are arranged in the buffer region 20. In the present specification, the doping concentration peak 211-1 closest to the lower surface 23 may be referred to as a shallowest doping concentration peak, and the doping concentration peak 211-5 furthest away from the lower surface 23 may be referred to as a deepest doping concentration peak.

The buffer region 20 has one or more hydrogen peaks 221 in the depth direction. The hydrogen peak 221 is a hydrogen chemical concentration peak. In the example shown in FIG. 4, in order from the peak closest to the lower surface 23 of the semiconductor substrate 10, a hydrogen peak 221-1, a hydrogen peak 221-2, a hydrogen peak 221-3, a hydrogen peak 221-4 and a hydrogen peak 221-5 are arranged in the buffer region 20. In the present specification, the hydrogen peak 221-1 closest to the lower surface 23 may be referred to as a shallowest peak, and the hydrogen peak 221-5 furthest away from the lower surface 23 may be referred to as a deepest peak. For the doping concentration peak 211-1 closest to the lower surface 23 of the semiconductor substrate 10, the dopants may be phosphorous. In this case, the peak 211-1 becomes a phosphorous peak 211-1.

The depth position of a local maximum of the hydrogen peak 221-m (m is an integer equal to or more than 1) is regarded as Zm. In the present specification, the position of the local maximum of the peak may be referred to as a peak position. The concentration in the local maximum of the peak may be referred to as peak concentration. The doping concentration peak 211-m may be arranged in a depth position Zm identical to the hydrogen peak 221-m. When the depth position of the local maximum of one peak is included within full width at half maximum in the depth direction of the other peak of two peaks, the two peaks may be considered to be arranged in the same depth position.

The semiconductor substrate 10 has a lower region 201 and an upper region 202. The lower region 201 is a region from the lower surface 23 to the deepest peak (the hydrogen peak 221-5 in the present example). The depth position at an upper end of the lower region 201 may be a depth position Z5 of a local maximum of the hydrogen peak 221-5, or may be a depth position where the hydrogen chemical concentration is equal to or lower than the detection lower limit on an upper surface 21 side further than the local maximum of the hydrogen peak 221-5 (Zb in the example shown in FIG. 4), or may be the depth position Zb of the boundary between the buffer region 20 and the drift region 18. In the present example, the upper end position of the lower region 201 is Zb. The lower region 201 in the present example includes the buffer region 20, but in another example, the lower region 201 may be a region different from the buffer region 20. In this case, the lower region 201 includes one or more hydrogen peaks 221.

The upper region 202 is a region arranged from the deepest peak (the hydrogen peak 221-5 in the present example) to the upper surface 21. The upper region 202 is arranged to be closer to the upper surface 21 side than the lower region 201. The depth position of a lower end of the upper region 202 may be identical to or may be different from the depth position of the upper end of the lower region 201. In the present example, the depth position of the lower end of the upper region 202 is Zb, identical to the depth position Zb of the upper end of the lower region 201. The upper region 202 may be the whole region from the depth position Zb to the upper surface 21, or may be a part of the region. In the present example, the upper region 202 is a part of the region from the depth position Zb to the upper surface 21. The upper end position Zu of the upper region 202 may be arranged in the drift region 18. The length in the depth direction of the upper region 202 (Zu-Zb in the present example) may be identical to, or shorter than, or longer than the length (Zb) in the depth direction of the lower region 201.

In the lower region 201, the carbon chemical concentration is regarded as Ca1, and the oxygen chemical concentration is regarded as Ox1. In the upper region 202, the carbon chemical concentration is regarded as Ca2, and the oxygen chemical concentration is regarded as Ox2. The carbon chemical concentration Ca1 and the oxygen chemical concentration Ox1 of the lower region 201 may use the average value, or may use the maximum value of the carbon chemical concentration and the oxygen chemical concentration of the lower region 201. The carbon chemical concentration Ca2 and the oxygen chemical concentration Ox2 of the upper region 202 may use the average value, or may use the maximum value of the carbon chemical concentration and the oxygen chemical concentration of the upper region 202.

For at least one of the carbon chemical concentration or the oxygen chemical concentration, the concentration of the lower region 201 is twice or more of the concentration of the upper region 202. In the example shown in FIG. 4, the carbon chemical concentration Ca1 of the lower region 201 is twice or more of the carbon chemical concentration Ca2 of the upper region 202, and the oxygen chemical concentration Ox1 of the lower region 201 is twice or more of the oxygen chemical concentration Ox2 of the upper region 202.

The carbon chemical concentration Ca1 may be 1×10¹⁴ atoms/cm³ or higher. The carbon chemical concentration Ca1 may be 5×10¹⁴atoms/cm³ or higher, or may be 1×10¹⁵atoms/cm³ or higher, or may be 5×10¹⁵atoms/cm³ or higher, or may be 1×10¹⁶atoms/cm³ or higher. The oxygen chemical concentration Ox1 may be 2×10¹⁷ atoms/cm³ or higher. The oxygen chemical concentration Ox1 may be 3×10¹⁷atoms/cm³ or higher, or may be 5×10¹⁷atoms/cm³ or higher.

In the semiconductor substrate 10 (semiconductor wafer) cut off from a semiconductor ingot, carbon and oxygen are distributed approximately uniformly. However, the carbon chemical concentration and the oxygen chemical concentration vary among the substrates. By implanting hydrogen ions into the semiconductor substrate 10, hydrogen donors are formed, for example, a region with a high concentration as the buffer region 20 may be formed. The degree of forming the hydrogen donors fluctuates depending on the carbon chemical concentration and the oxygen chemical concentration of the semiconductor substrate 10 with respect to the dose amount of the hydrogen ions. For example, the degree of forming a VOH defect fluctuates depending on the oxygen chemical concentration, and the degree of forming CiOi-H fluctuates depending on the oxygen chemical concentration and the carbon chemical concentration. Therefore, the doping concentration of a high concentration region like the buffer region 20 fluctuates depending on the carbon chemical concentration and the oxygen chemical concentration of the semiconductor substrate 10.

In the semiconductor device 100 in the present example, by selectively implanting at least one of carbon or oxygen into the lower region 201 of the semiconductor substrate 10, at least one of the carbon chemical concentration or the oxygen chemical concentration in the lower region 201 is adjusted. This allows reducing the effect of variations in the carbon chemical concentration and the oxygen chemical concentration of the semiconductor substrate 10, and to precisely control the doping concentration in the lower region 201 (the buffer region 20 in the present example).

For one or both of the carbon chemical concentration and the oxygen chemical concentration, the concentration of the lower region 201 may be 5 times or more, or may be 10 times or more of the concentration of the upper region 202. The dose amount of carbon and oxygen implanted into the lower region 201 can be relatively precisely controlled. This allows reducing ratios of the variations in the carbon chemical concentration and the oxygen chemical concentration to the entirety of the carbon chemical concentration and the oxygen chemical concentration in the semiconductor substrate 10 by implanting much carbon or oxygen into the lower region 201. For both of the carbon chemical concentration and the oxygen chemical concentration, the concentration of the lower region 201 may be 1000 times or less, or may be 100 times or less, or may be 50 times or less of the concentration of the upper region 202.

The lower region 201 in the present example has a flat portion 231. In the flat portion 231, at least one of the carbon chemical concentration or the oxygen chemical concentration, which is twice or more when compared to the concentration of the upper region 202, is uniform. In the flat portion 231 in the example shown in FIG. 4, both of the carbon chemical concentration and the oxygen chemical concentration are uniform. In the flat portion 231, for at least one of the carbon chemical concentration or the oxygen chemical concentration, the maximum concentration may be 1.1 times or less, or may be 1.07 times or less, or may be 1.05 times or less of the minimum concentration. The length in the depth direction of the flat portion 231 may be 10% or more, or may be 30% or more, or may be 50% or more, or may be 70% or more, or may be 90% or more, or may be 100% of the lower region 201. The length in the depth direction of the flat portion 231 may be 5 μm or longer, or may be 10 μm or longer, or may be 20 μm or longer. By providing the flat portion 231, the hydrogen donor concentration and the doping concentration of the lower region 201 can be precisely controlled.

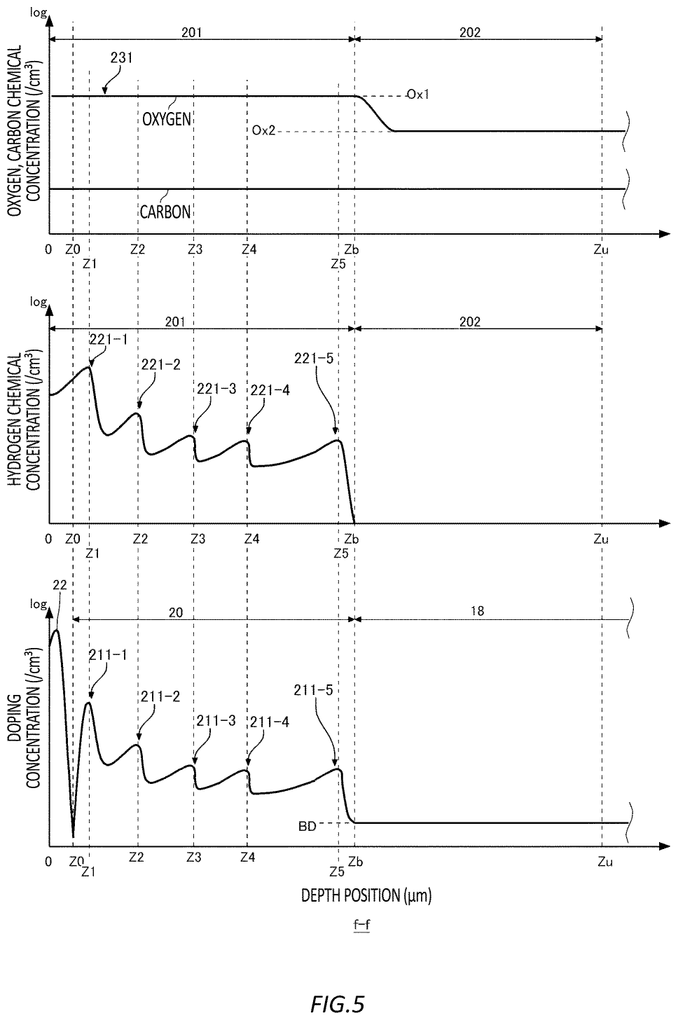

FIG. 5 illustrates another example of each distribution of the doping concentration, the hydrogen chemical concentration, the oxygen chemical concentration and the carbon chemical concentration on the line f-f of FIG. 3. In the present example, the distribution of the carbon chemical concentration is different from the example shown in FIG. 4. Other distributions are similar to the example distributions of FIG. 4.

The carbon concentration of the lower region 201 in the present example is less than twice of the carbon concentration of the upper region 202. The carbon concentration of the lower region 201 may be 1.5 times or less of the carbon concentration of the upper region 202, or may be identical to the carbon concentration of the upper region 202. In the present example, oxygen is locally implanted, but carbon is not locally implanted in the lower region 201. By increasing the oxygen chemical concentration of the lower region 201, the variations in the doping concentration due to the variations in the oxygen chemical concentration can be suppressed.

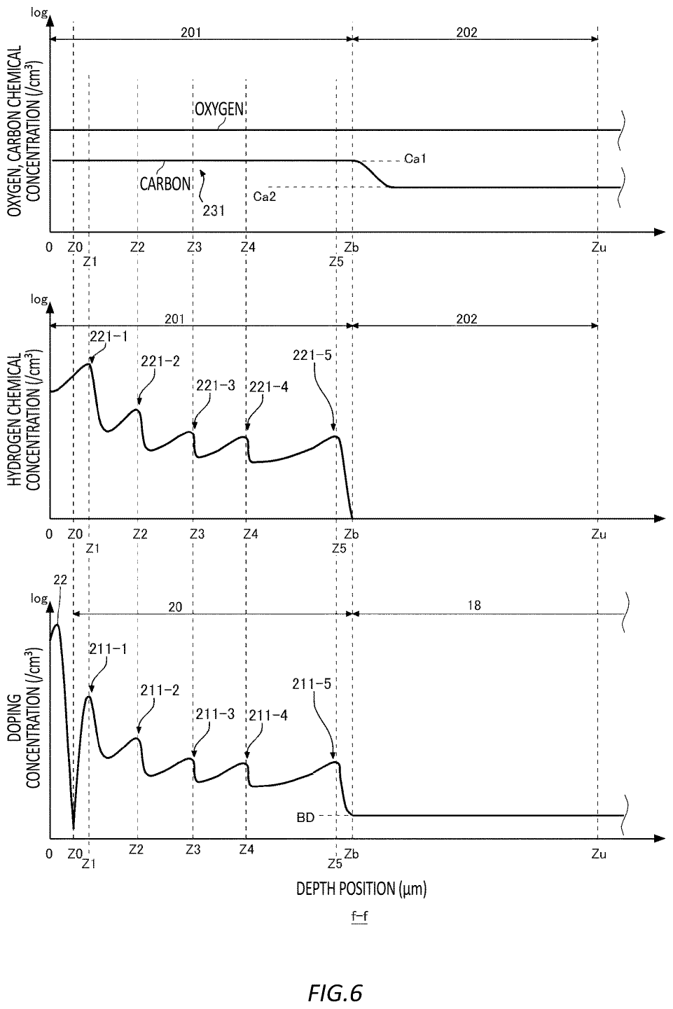

FIG. 6 illustrates another example of each distribution of the doping concentration, the hydrogen chemical concentration, the oxygen chemical concentration and the carbon chemical concentration on the line f-f of FIG. 3. In the present example, the distribution of the oxygen chemical concentration is different from the example of FIG. 4. Other distributions are similar to the example distributions of FIG. 4.

The oxygen concentration of the lower region 201 in the present example is less than twice of the oxygen concentration of the upper region 202. The oxygen concentration of the lower region 201 may be 1.5 times or less of the oxygen concentration of the upper region 202, or may be identical to the oxygen concentration of the upper region 202. In the present example, carbon is locally implanted, but the oxygen is not locally implanted in the lower region 201. By increasing the carbon chemical concentration of the lower region 201, the variations in the doping concentration due to the variations in the carbon chemical concentration can be suppressed.

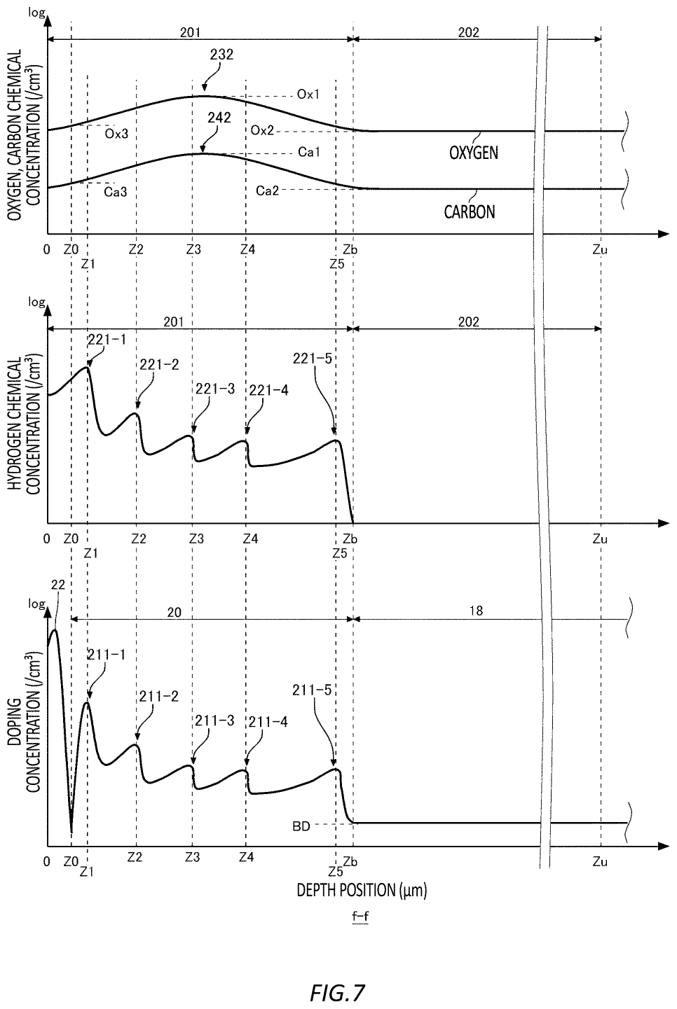

FIG. 7 illustrates another example of each distribution of the doping concentration, the hydrogen chemical concentration, the oxygen chemical concentration and the carbon chemical concentration on the line f-f of FIG. 3. In the present example, the distribution of at least one of the oxygen chemical concentration or the carbon chemical concentration is different from any example shown in FIG. 4 to FIG. 6. Other distributions are similar to any example shown in FIG. 4 to FIG. 6. In FIG. 7, although both of the oxygen chemical concentration and the carbon chemical concentration are different from any example shown in FIG. 4 to FIG. 6, one of the oxygen chemical concentration and the carbon chemical concentration may be identical to any example shown in FIG. 4 to FIG. 6.

The lower region 201 in the present example has one or more carbon peaks 242 that are peaks of the carbon chemical concentration in the depth direction. In the example of FIG. 7, there is one carbon peak 242. The local maximum position of the carbon peak 242 may be arranged in a vicinity of the center of the lower region 201 in the depth direction. The vicinity of the center may refer to a central region when the lower region 201 is divided into three equal parts in the depth direction. The full width at half maximum of the carbon peak 242 in the depth direction may be 50% or more, or may be 70% or more, or may be 90% or more, or may be 100% or more of the length Zb of the lower region 201 in the depth direction.

The carbon chemical concentration in the depth position Zb may be higher than the carbon chemical concentration Ca2 of the upper region 202. The carbon chemical concentration in the depth position Z0 may be higher than the carbon chemical concentration Ca2 of the upper region 202. The carbon chemical concentration in the local maximum position Zm of each hydrogen peak 221-m may be higher than the carbon chemical concentration Ca2 of the upper region 202, or may be 1.5 times or more, or may be twice or more, or may be 5 times or more, or may be 10 times or more of the carbon chemical concentration Ca2 of the upper region 202. The carbon chemical concentration Ca1 of the carbon peak 242 is twice or more of the carbon chemical concentration Ca2 of the upper region 202. The carbon chemical concentration Ca1 of the carbon peak 242 may be 5 times or more, or may be 10 times or more of the carbon chemical concentration Ca2 of the upper region 202.

By arranging an absorber on an implantation surface of carbon ions and adjusting a projected range of carbon ions while accelerating carbon ions with relatively stronger acceleration energy, the carbon peak 242 can be provided with a magnitude of relatively full width at half maximum as shown in FIG. 7. The present example allows the variations in doping concentration due to variations in carbon chemical concentration to be suppressed.

The lower region 201 in the present example has one or more oxygen peaks 232 that are oxygen chemical concentration peaks in the depth direction. In the example in FIG. 7, there is one oxygen peak 232. The local maximum position of the oxygen peak 232 may be arranged in the vicinity of the center of the lower region 201 in the depth direction. The full width at half maximum of the oxygen peak 232 in the depth direction may be 50% or more, or may be 70% or more, or may be 90% or more, or may be 100% or more of the length Zb of the lower region 201 in the depth direction.

The oxygen chemical concentration in the depth position Zb may be higher than the oxygen chemical concentration Ox2 of the upper region 202.

The oxygen chemical concentration in the depth position Z0 may be higher than the oxygen chemical concentration Ox2 of the upper region 202. The oxygen chemical concentration in the local maximum position Zm of each hydrogen peak 221-m may be higher than the oxygen chemical concentration Ox2 of the upper region 202, or may be 1.5 times or more, or may be twice or more, or may be 5 times or more, or may be 10 times or more of the carbon chemical concentration Ox2 of the upper region 202. The oxygen chemical concentration Ox1 of the oxygen peak 232 is twice or more of the oxygen chemical concentration Ox2 of the upper region 202. The oxygen chemical concentration Ox1 of the oxygen peak 232 may be 5 times or more, or may be 10 times or more of the oxygen chemical concentration Ox2 of the upper region 202. The present example allows variations in the doping concentration due to the variations in the oxygen chemical concentration to be suppressed.

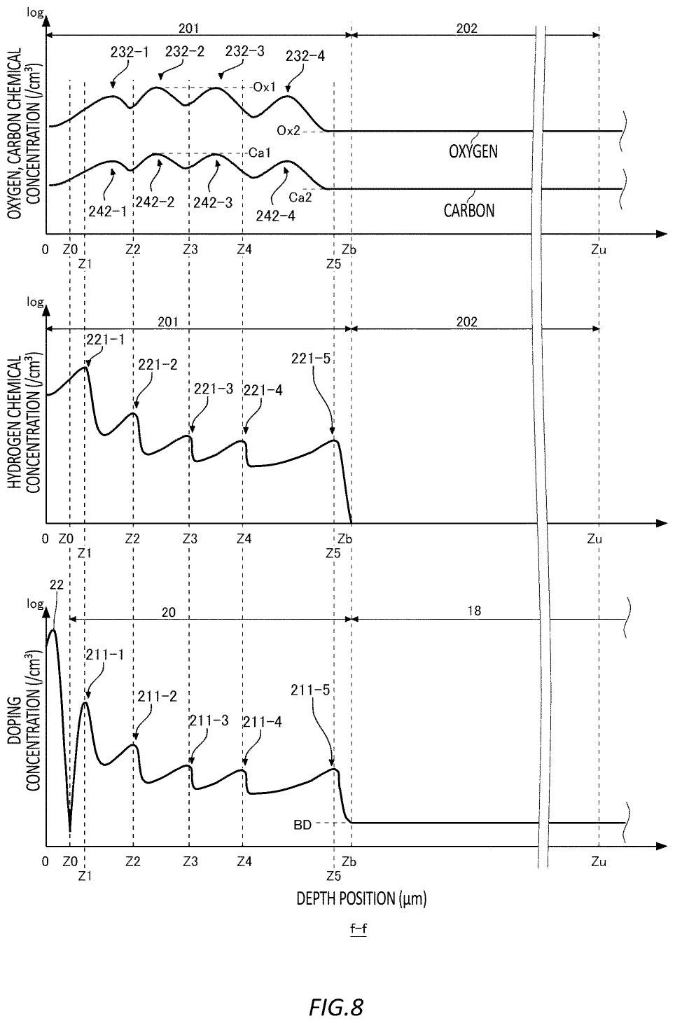

FIG. 8 illustrates another example of each distribution of the doping concentration, the hydrogen chemical concentration, the oxygen chemical concentration and the carbon chemical concentration on the line f-f of FIG. 3. In the present example, the distribution of at least one of the oxygen chemical concentration or the carbon chemical concentration is different from any example shown in FIG. 4 to FIG. 7. Other distributions are similar to any example shown in FIG. 4 to FIG. 7. In FIG. 8, although both of the oxygen chemical concentration and the carbon chemical concentration are different from any example shown in FIG. 4 to FIG. 7, one of the oxygen chemical concentration and the carbon chemical concentration may be identical to any example shown in FIG. 4 to FIG. 7.

The lower region 201 in the present example has a plurality of carbon peaks 242 in the depth direction. In the present example, at least one carbon peak 242 is arranged between two hydrogen peaks 221 in the depth direction. When the local maximum of the carbon peak 242 is arranged in the central region when the region between the local maximums of two hydrogen peaks 221 is divided into three equal parts in the depth direction, the carbon peak 242 may be considered to be arranged between the local maximums of two hydrogen peaks 221. In another example, when the local maximum of the carbon peak 242 is arranged between the local maximums of two hydrogen peaks 221, and the local maximum of the carbon peak 242 is not arranged in the range of full width at half maximum of two hydrogen peaks 221, the carbon peak 242 may be considered to be arranged between the local maximums of two hydrogen peaks 221.

All the carbon peaks 242 may be arranged between two hydrogen peaks 221 in the depth direction. The carbon peak 242-m may be arranged between the hydrogen peak 221-m and the hydrogen peak 221-(m+1). The number of the carbon peaks 242 may be less than the number of the hydrogen peaks 221 in the depth direction.

Arranging the carbon peak 242 between two hydrogen peaks 221 can make the depth position to implant carbon ions different from the depth position to implant hydrogen ions. This allows a density of the lattice defect formed due to ion implantation to be suppressed, so as not to become locally excessively high.

The lower region 201 in the present example has a plurality of oxygen peaks 232 in the depth direction. In the present example, at least one oxygen peak 232 is arranged between two hydrogen peaks 221 in the depth direction. When the local maximum of the oxygen peak 232 is arranged in the central region when the region between the local maximums of two hydrogen peaks 221 is divided into three equal parts in the depth direction, the oxygen peak 232 may be considered to be arranged between the local maximums of two hydrogen peaks 221. In another example, when the local maximum of the oxygen peak 232 is arranged between the local maximums of two hydrogen peaks 221, and the local maximum of the oxygen peak 232 is not arranged in the range of full width at half maximum of two hydrogen peaks 221, the oxygen peak 232 may be considered to be arranged between the local maximums of two hydrogen peaks 221.

All the oxygen peaks 232 may be arranged between two hydrogen peaks 221 in the depth direction. The oxygen peak 232-m may be arranged between the hydrogen peak 221-m and the hydrogen peak 221-(m+1). The number of the oxygen peaks 232 may be less than the number of the hydrogen peaks 221 in the depth direction.

Arranging the oxygen peak 232 between two hydrogen peaks 221 can make the depth position to implant oxygen ions different from the depth position to implant hydrogen ions. This allows a density of the lattice defect formed due to ion implantation to be suppressed, so as not to become locally excessively high.

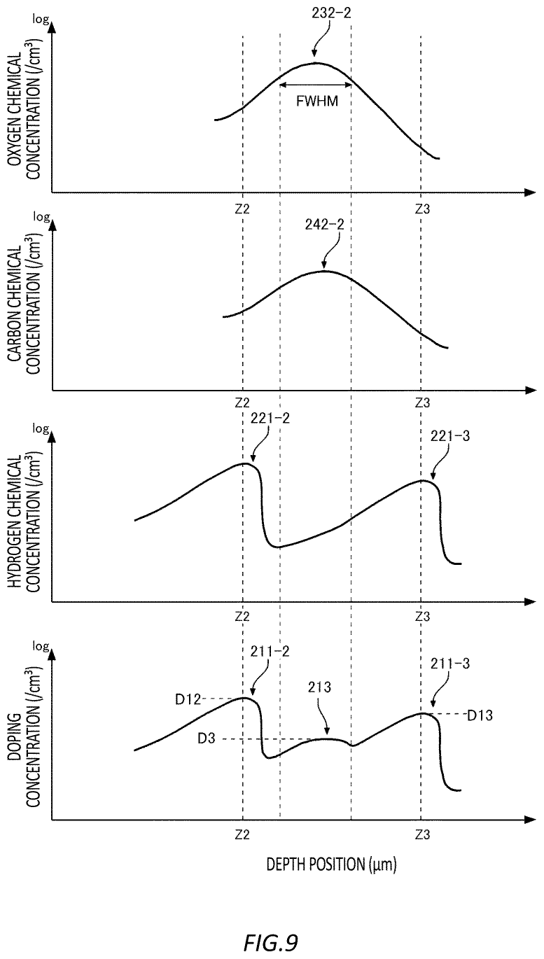

FIG. 9 illustrates one example of relative positions of the oxygen peak 232 and the carbon peak 242. The lower region 201 in the present example has one or more carbon peaks 242 and one or more oxygen peaks 232 in the depth direction. At least one carbon peak 242 is arranged in an depth position identical to at least one oxygen peak 232. In the example of FIG. 9, the example where the oxygen peak 232-2 is arranged in a depth position identical to the carbon peak 242-2 is shown, but another oxygen peak 232-m may be arranged in a depth position identical to the carbon peak 242-m. In the present example, the local maximum of the carbon peak 242-2 is arranged inside the range of full width at half maximum FWHM of the oxygen peak 232-2. In another example, the local maximum of the oxygen peak 232-2 may be arranged inside the range of full width at half maximum of the carbon peak 242-2.

When the oxygen peak 232 and the carbon peak 242 are arranged in an identical depth position, both the oxygen chemical concentration and the carbon chemical concentration in the vicinity of the position are increased. Therefore, the concentration of hydrogen donors such as CiOi-H in the vicinity of the position can be stabilized to suppress variations in the doping concentration.

The hydrogen donors such as CiOi-H are more likely to form in the vicinity of the local maximums of the oxygen peak 232-2 and the carbon peak 242-2. Therefore, the second doping concentration peak 213 may be formed in the depth position of the local maximums of the oxygen peak 232-2 and the carbon peak 242-2. As shown in FIG. 9, when the oxygen peak 232-2 and the carbon peak 242-2 are arranged between two of the hydrogen peak 221-2 and the hydrogen peak 221-3, the second doping concentration peak 213 may be arranged between two of the doping concentration peak 211-2 and the doping concentration peak 211-3. The doping concentration peak 211 in the present example is one example of the first doping concentration peak.

The doping concentration of the second doping concentration peak 213 is regarded as D3. The doping concentration of the doping concentration peak 211-2 is regarded as D12, and the doping concentration of the doping concentration peak 211-3 is regarded as D13, which are adjacent to the second doping concentration peak 213 in the depth direction. The doping concentration D3 may be lower than any of the doping concentration D12 or D13. The doping concentration D3 may be 50% or less, or may be 30% or less with respect to any of the doping concentration D12 or D13. The doping concentration D3 may be 1% or more, or may be 10% or more with respect to any of the doping concentration D12 or D13. According to the present example, the doping concentration distribution between the doping concentration peaks 211 can be flattened.

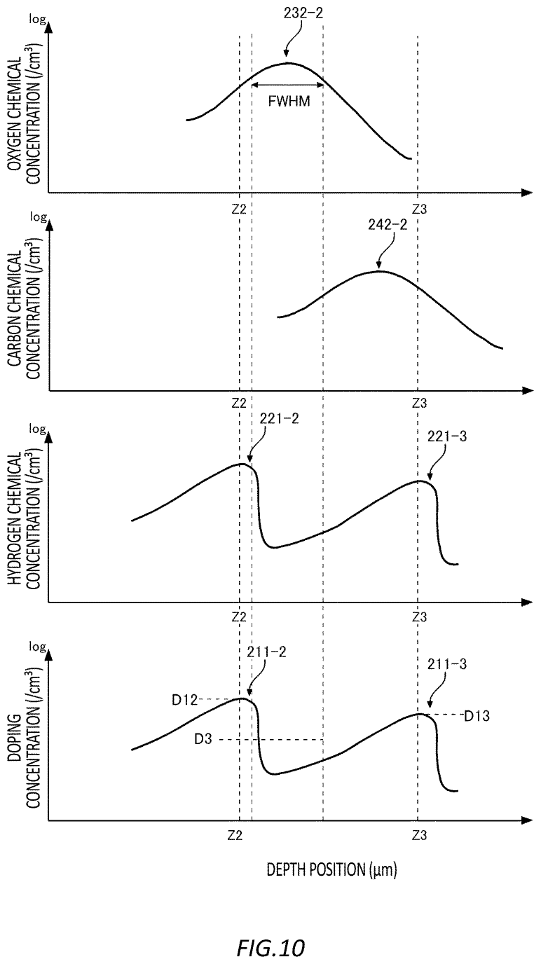

FIG. 10 illustrates another example of relative positions of the oxygen peak 232 and the carbon peak 242. The lower region 201 in the present example has one or more carbon peaks 242 and one or more oxygen peaks 232 in the depth direction. At least one carbon peak 242 is arranged in an depth position different from any oxygen peak 232. At least one oxygen peak 232 is arranged in an depth position different from any carbon peak 242.

In the example of FIG. 10, the example where the oxygen peak 232-2 is not arranged in a depth position identical to the carbon peak 242-2 is shown, but another oxygen peak 232-m may not be arranged in a depth position identical to the carbon peak 242-m. In another example, among the combination of the oxygen peaks 232-m and the carbon peaks 242-m, some oxygen peaks 232-m and carbon peaks 242-m are arranged in identical depth positions, and other oxygen peaks 232-m and other carbon peaks 242-m may not be arranged in identical depth positions.

In the present example, the local maximum of the carbon peak 242-2 is arranged outside the range of full width at half maximum FWHM of the oxygen peak 232-2. The local maximum of the oxygen peak 232-2 is arranged outside the range of full width at half maximum of the carbon peak 242-2. According to the present example, the density of the lattice defect formed due to implantation of oxygen ions and implantation of carbon ions can be suppressed, so as not to become locally excessively high.

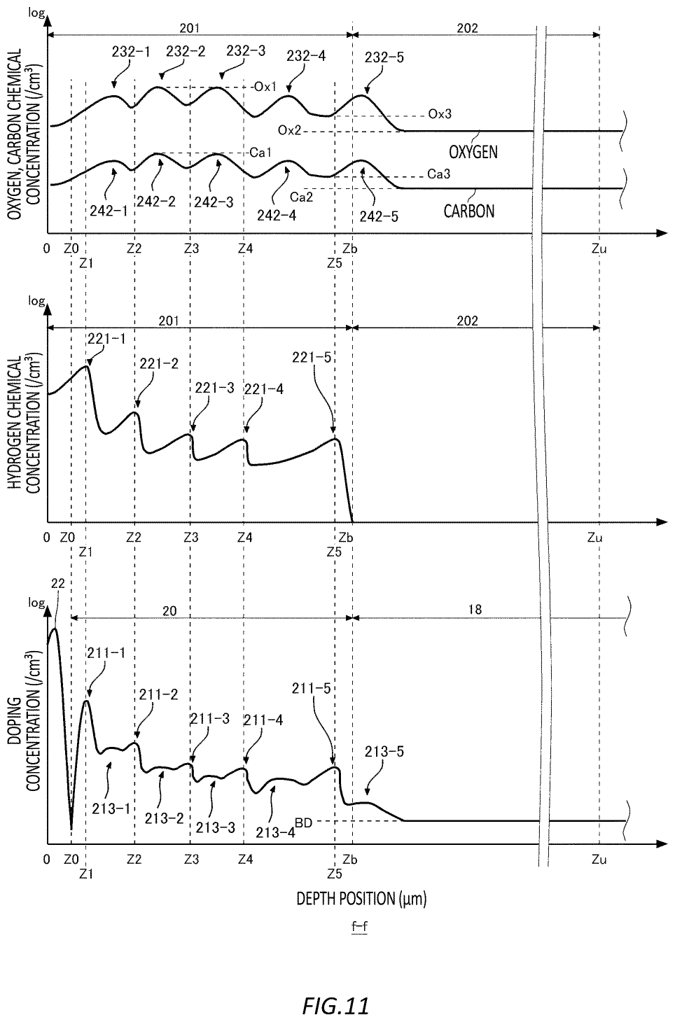

FIG. 11 illustrates another example of each distribution of the doping concentration, the hydrogen chemical concentration, the oxygen chemical concentration and the carbon chemical concentration on the line f-f of FIG. 3. In the present example, the upper region 202 has at least one of one or more carbon peaks 242 or one or more oxygen peaks 232. The upper region 202 shown in FIG. 11 has one carbon peak 242-5 and one oxygen peak 232-5.

The carbon peak 242-4 and the oxygen peak 232-5 are arranged to be closer to the upper surface 21 side than the hydrogen peak 221-5. The carbon peak 242-5 may be arranged in the vicinity of the carbon peak 242-4. The carbon peak 242-5 may be arranged so that the minimum value Ca3 of the carbon chemical concentration between the carbon peak 242-4 and the carbon peak 242-5 becomes higher than the carbon chemical concentration Ca2 of the upper region 202. The carbon chemical concentration Ca3 may be twice or more of the carbon chemical concentration Ca2. According to the present example, the carbon chemical concentration can be increased in the vicinity of the depth position Zb. Therefore, the doping concentration of the buffer region 20 in the vicinity of the depth position Zb can be stabilized.

The oxygen peak 232-5 may be arranged in the vicinity of the oxygen peak 232-4. The oxygen peak 232-5 may be arranged so that the minimum value Ox3 of the oxygen chemical concentration between the oxygen peak 232-4 and the oxygen peak 232-5 becomes higher than the oxygen chemical concentration Ox2 of the upper region 202. The oxygen chemical concentration Ox3 may be twice or more of the oxygen chemical concentration Ox2. According to the present example, the oxygen chemical concentration can be increased in the vicinity of the depth position

Zb. Therefore, the doping concentration of the buffer region 20 in the vicinity of the depth position Zb can be stabilized.

The doping concentration distribution in the present example has a plurality of second doping concentration peaks 213. There is one second doping concentration peak 213 arranged between every two hydrogen peaks 221. The carbon peak 242-4 and the oxygen peak 232-5 may be arranged in an identical depth position. In this case, the second doping concentration peak 213-5 may be arranged to be closer to the upper surface 21 side than the doping concentration peak 211-5. This allows the doping concentration in the vicinity of the depth position Zb to fluctuate moderately. Therefore, oscillation of the voltage between the emitter and collector can be suppressed when the space charge region (depletion layer) extending from the boundary between the drift region 18 and base region 14 reaches the vicinity of the depth position Zb during turn-off of the semiconductor device 100, etc.

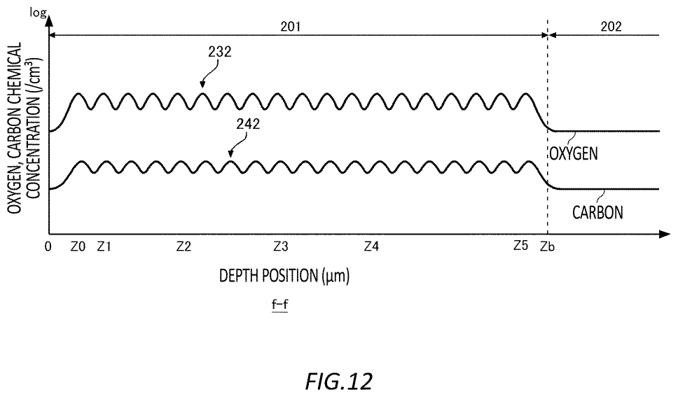

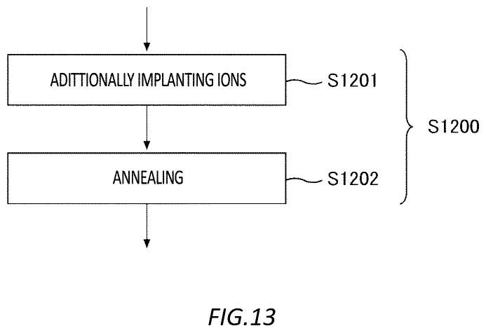

FIG. 12 illustrates another example of each distribution of the oxygen chemical concentration and the carbon chemical concentration on the line f-f of FIG. 3. The lower region 201 in the present example has more peaks of at least one of the oxygen chemical concentration or the carbon chemical concentration than the hydrogen peaks 221. The lower region 201 shown in FIG. 12 has more peaks of both of the oxygen chemical concentration and the carbon chemical concentration than the hydrogen peaks 221. By varying the acceleration energy of the ions implanted into the semiconductor substrate 10 in steps, a large number of concentration peaks can be formed. According to the present example, at least one of the oxygen chemical concentration or the carbon chemical concentration in the lower region 201 can be flattened. By increasing the density of the peaks in the depth direction, the flat portion 231 can be formed as shown in FIG. 4. FIG. 13 illustrates a view showing part of a process of a method for manufacturing the semiconductor device 100. In FIG. 13, a step S1200 of adjusting concentration of implanting at least one of carbon, oxygen or silicon into the lower region 201 for annealing is shown. The step S1200 of adjusting concentration is included in a manufacturing step of the semiconductor device 100. The step S1200 of adjusting concentration is conducted prior to a step of implanting hydrogen ions into the lower region 201.

The step S1200 of adjusting concentration includes a step S1201 of implanting ions and a step S1202 of annealing. In the step S1201 of implanting ions, at least one of carbon, oxygen or silicon is implanted into a region for forming the lower region 201. In the example shown in FIG. 1 to FIG. 12, although at least one of carbon or oxygen has been implanted into the lower region 201, the concentration of hydrogen donors formed in the lower region 201 can be adjusted by implanting silicon into the lower region 201. In the step S1201 of implanting ions, at least one of the carbon concentration or the oxygen concentration in the semiconductor substrate 10 may be measured, and the dose amount of at least one of carbon or oxygen may be adjusted based on the measurement result. In the step S1201 of implanting ions, the dose amount of at least one of carbon or oxygen may be adjusted based on a difference between at least one of the carbon concentration or the oxygen concentration in the semiconductor substrate 10 and a predetermined reference value.

In the step S1202 of annealing, the semiconductor substrate 10 is annealed by furnace annealing or other means. An annealing temperature in the step S1202 of annealing is 700° C. or higher. The annealing temperature may be 750° C. or higher, or may be 800° C. or higher in the step S1202 of annealing. Annealing at a relatively high temperature can diffuse carbon or the like implanted into the lower region 201 and make the distribution of carbon or the like in the lower region 201 more uniform. After the step S1202 of annealing, hydrogen ions are implanted into the lower region 201 to form the buffer region 20. Because the concentration of carbon or the like in the lower region 201 is adjusted, the doping concentration in the lower region 201 can be precisely controlled.

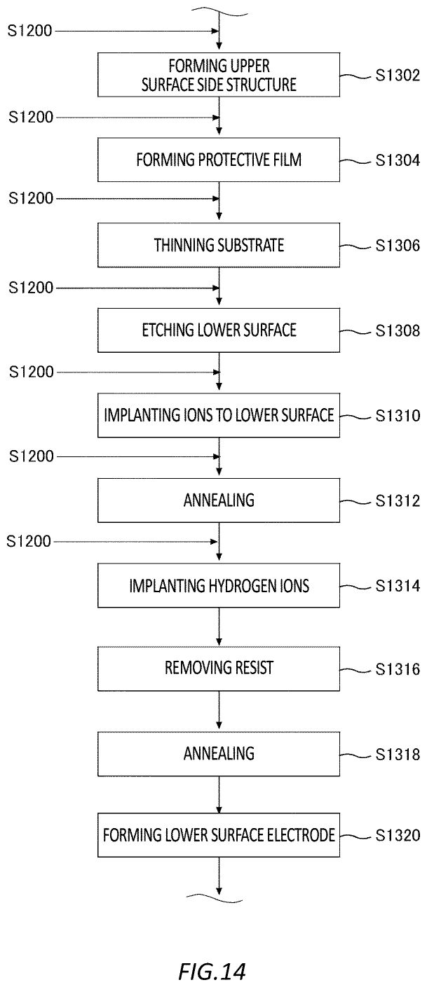

FIG. 14 illustrates an outline of a manufacturing method of the semiconductor device 100. The manufacturing method of the semiconductor device 100 may have steps other than the steps shown in FIG. 14, or may not have a part of the steps shown in FIG. 14.

The manufacturing method in the present example forms a structure on the upper surface 21 side of the semiconductor substrate 10 in a step S1302 of forming upper surface side structure. The structure on the upper surface 21 side is, for example, a structure on the upper side further than the center of the semiconductor substrate 10 in the depth direction. The structure on the upper surface 21 side includes at least some of the emitter region 12, the base region 14, the trench portion, the dielectric film, the gate runner, the gate pad 164 or the emitter electrode 52.

In the next step S1304 of forming protective film, a protective film that covers at least some regions of the emitter electrode 52, the gate pad 164 or the gate runner is formed. For example, the protective film is a polyimide film. The protective film may cover a region of the emitter electrode 52, gate pad 164, and gate runner to which wires or lead frames or other wiring are not connected.

Then in a step S1306 of thinning substrate, the lower surface of the semiconductor substrate 10 is ground to thin the semiconductor substrate 10. In the step S1306 of thinning substrate, the semiconductor substrate 10 may be thinned depending on a breakdown voltage that the semiconductor device 100 should have. In the step S1306 of thinning substrate, the semiconductor substrate 10 may be ground by a CMP method or the like.

Then in a step S1308 of etching lower surface, the lower surface of the semiconductor substrate 10 is etched. This removes a region where damage is applied in the step S1306 of thinning substrate.

Then in a step S1310 of implanting ions into lower surface, the dopant ions are implanted into the lower surface 23 of the semiconductor substrate 10. In a step S1310 of implanting ions into lower surface, dopant ions are implanted into a region where the collector region 22 and the cathode region 82 should be formed. Then in a step S1312 of annealing, the collector region 22 and cathode region 82 are laser annealed to activate the dopants.

Then in a step S1314 of implanting hydrogen ions, hydrogen ions are implanted from the lower surface 23 in a region where the buffer region 20 should be formed. In the step S1314 of implanting hydrogen ions, hydrogen ions are implanted into depth positions where one or more hydrogen peaks 221 should be formed.

Prior to the step S1314 of implanting hydrogen ions, a resist may be formed on the lower surface 23. The projected range of the hydrogen ions may be adjusted by the resist. Then in a step S1316 of removing resist, the resist of the lower surface 23 is removed. Then in a step S1318 of annealing, the semiconductor substrate 10 is annealed by furnace annealing or other means. In this way, the hydrogen donors are formed, and the buffer region 20 is formed. The annealing temperature in the step S1318 of annealing is 400° C. or lower. The annealing temperature in the step S1318 of annealing may be 390° C. or lower, or may be 380° C. or lower. Then in a step S1320 of forming lower surface electrode, the collector electrode 24 is formed. The collector electrode 24 may be formed by sputtering or other means.

As shown in FIG. 14, the step S1200 of adjusting concentration is conducted at any timing prior to the step S1314 of implanting hydrogen ions. By conducting the step S1202 of annealing at a relatively high temperature prior to the step S1314 of implanting hydrogen ions, the loss of hydrogen donors due to high temperature annealing can be suppressed.

The step S1200 of adjusting concentration may be conducted prior to the step S1302 of forming upper surface side structure, or may be conducted prior to the step S1304 of forming protective film, or may be conducted prior to the step S1306 of thinning substrate. When conducting the step S1200 of adjusting concentration prior to the step S1306 of thinning substrate, carbon, oxygen and silicon ions may be implanted from the upper surface 21 of the semiconductor substrate 10. When conducting the step S1200 of adjusting concentration after the step S1306 of thinning substrate, carbon, oxygen and silicon ions may be implanted from the lower surface 23 of the semiconductor substrate 10.

The step S1200 of adjusting concentration may be conducted prior to the step S1308 of etching lower surface, or may be conducted prior to the step S1310 of implanting ions into lower surface, or may be conducted prior to the step S1312 of annealing. Steps after the step S1200 of adjusting concentration are conducted at a temperature of 400° C. or lower. The steps after the step S1200 of adjusting concentration may be conducted at a temperature of 390° C. or lower, or may be conducted at a temperature of 380° C. or lower.

While the present invention has been described by way of the embodiments, the technical scope of the present invention is not limited to the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

The operations, procedures, steps, stages, or the like of each process performed by a device, system, program, and method shown in the claims, specification, or drawings can be performed in any order as long as the order is not indicated by “prior to,” “before,” or the like and as long as the output from a previous process is not used in a later process. Even if the operation flow is described using phrases such as “first” or “then” in the claims, specification, or drawings, it does not necessarily mean that the process must be performed in this order.

What is claimed is:

1. A semiconductor device, comprising a semiconductor substrate with an upper surface and a lower surface, wherein:
the semiconductor substrate has one or more hydrogen peaks, which are peaks of a hydrogen chemical concentration, in a depth direction, and the one or more hydrogen peaks include a deepest peak furthest away from the lower surface of the semiconductor substrate;
the semiconductor substrate has a lower region from the lower surface to the deepest peak, and an upper region arranged from the deepest peak to the upper surface; and
for at least one of a carbon chemical concentration or an oxygen chemical concentration, a concentration in the lower region is twice or more of a concentration of the upper region.

2. The semiconductor device according to claim 1, wherein:
the semiconductor substrate has:
a drift region of a first conductivity type; and
a buffer region of the first conductivity type arranged between the lower surface and the drift region, with a higher doping concentration than the drift region; and
wherein the deepest peak is arranged in the buffer region.

3. The semiconductor device according to claim 1, wherein the lower region has a flat portion where at least one of the carbon chemical concentration or the oxygen chemical concentration is uniform.

4. The semiconductor device according to claim 1, wherein the lower region has one or more carbon peaks that are peaks of the carbon chemical concentration in the depth direction.

5. The semiconductor device according to claim 4, wherein the lower region has a plurality of the carbon peaks in the depth direction.

6. The semiconductor device according to claim 4, wherein:
the lower region has a plurality of the hydrogen peaks in the depth direction; and
at least one of the carbon peaks is arranged between two of the hydrogen peaks in the depth direction.

7. The semiconductor device according to claim 4, wherein the upper region has one or more of the carbon peaks.

8. The semiconductor device according to claim 1, wherein the lower region has one or more of the oxygen peaks that are peaks of the oxygen chemical concentration in the depth direction.

9. The semiconductor device according to claim 8, wherein the lower region has a plurality of the oxygen peaks in the depth direction.

10. The semiconductor device according to claim 8, wherein:
the lower region has a plurality of the hydrogen peaks in the depth direction; and
at least one of the oxygen peaks is arranged between two of the hydrogen peaks in the depth direction.

11. The semiconductor device according to claim 8, wherein the upper region has one or more of the oxygen peaks.

12. The semiconductor device according to claim 1, wherein the lower region has one or more carbon peaks that are peaks of the carbon chemical concentration and one or more oxygen peaks that are peaks of the oxygen chemical concentration in the depth direction.

13. The semiconductor device according to claim 12, wherein at least one of the carbon peaks and at least one of the oxygen peaks are arranged in an identical depth position.

14. The semiconductor device according to claim 13, wherein:
the lower region has a plurality of doping concentration peaks in the depth direction; and
the plurality of doping concentration peaks include:
a plurality of first doping concentration peaks corresponding to a plurality of the hydrogen peaks; and
a second doping concentration peak arranged between two of the hydrogen peaks.

15. The semiconductor device according to claim 12, wherein at least one of the carbon peaks is arranged in depth positions different from any of the oxygen peaks.

16. The semiconductor device according to claim 1, wherein the carbon chemical concentration in the lower region is 1×10¹⁴ atoms/cm³ or higher.

17. The semiconductor device according to claim 1, wherein the oxygen chemical concentration in the lower region is 2×10¹⁷ atoms/cm³ or higher.

18. A manufacturing method of a semiconductor device, wherein:
the semiconductor device comprises
a semiconductor substrate with an upper surface and a lower surface;
the semiconductor substrate has one or more hydrogen peaks that are hydrogen chemical concentration peaks in a depth direction, and one or more of the hydrogen peaks include a deepest peak furthest away from the lower surface of the semiconductor substrate;
the semiconductor substrate has a lower region arranged from the lower surface to the deepest peak, and an upper region from the deepest peak to the upper surface; and
the manufacturing method
implants at least one of carbon, oxygen or silicon into a region where the lower region should be formed;
anneals the semiconductor substrate at a temperature of 700°° C. or higher; and
implants hydrogen ions in depth positions where one or more of the hydrogen peaks are to be formed.

19. The semiconductor device according to claim 2, wherein the carbon chemical concentration in the lower region is 1×10¹⁴ atoms/cm³ or higher.

20. The semiconductor device according to claim 3, wherein the carbon chemical concentration in the lower region is 1×10¹⁴ atoms/cm³ or higher.
